(19) United States
(12) Patent Application Publication
(10) Pub. No.: US 2012/0318337 A1
(43) Pub. Date: Dec. 20, 2012

(54) Solar Cell

(76) Inventors: Keiji Watanabe, Kokubunji (JP); Takashi Hattori, Musashimurayama (JP); Mieko Matsumura, Kokubunji (JP); Ryuta Tsuchiya, Tokyo (JP); Mutsuko Hatano, Tokyo (JP)

(21) Appl. No.: 13/521,487

(22) PCT Filed: Feb. 17, 2012
(86) PCT No.: PCT/JP2011/053398

§ 371 Date: Aug. 29, 2012

(30) Foreign Application Priority Data
Mar. 24, 2010 (JP) 2010=067206

(51) Int. Cl. H01L 31/076

(52) U.S. Cl. 136/255

(57) ABSTRACT

In a conventional solar cell, it has been difficult to ensure a sufficient light absorption and simultaneously to prevent current loss due to the reduction of the moving distance of electrons and holes. As a means for solving this difficulty, a plurality of a p-i-n junctions are stacked through an insulating film and are connected in parallel with each other using through-electrodes. In this case, the through-electrodes and the p-i-n junctions are connected through the p-layer or the n-layer, thereby moving electrons and holes in opposite directions and generating output current. In addition, the i-layer is made thicker than the p-layer and the n-layer in each of the p-i-n junctions, thereby ensuring a sufficient light absorption and simultaneously preventing current loss.

### TECHNICAL FIELD

The present invention is related to a solar cell.

### BACKGROUND ART

A solar cell needs to have a thickness sufficient to allow sunlight falling thereon to be absorbed. However, a problem exists in that while an electron and a hole, generated due to optical absorption, move across a distance corresponding to the thickness, there occurs recombination of the electron with the hole depending on a constituent material of the solar cell, thereby causing a loss in output current of the solar cell. In the case of the constituent material of a thin-film solar cell recently attracting attention, in particular, an electron as well as a hole has a short lifetime, the problem is therefore quite serious. In order to solve the problem, a technology capable of striking a good balance between optical absorption and reduction in current loss is much sought after.

### CITATION LIST

### Patent Literature

Patent Document 1: Japanese Unexamined Patent Application Publication (Translation of PCT Application) No. Hei9 (1997)-511102

### SUMMARY OF INVENTION

### Technical Problem

In Patent Document 1, a technique whereby a solar cell is made up by parallel connection of pn junctions that are alternately stacked has been proposed as a candidate technique for striking a balance between optical absorption and reduction in current loss. The technique has a merit in that even if respective p-layers as well as respective n-layers are decreased in film thickness, sufficient optical absorption can be ensured by increasing the number of stacked layers. However, the technique described in Patent Document 1 has had a problem in that a layer responsible for optical absorption has been set to be the n-layer, and the p-layer, respectively, so that a minority of carriers that are generated will inevitably have a shorter lifetime. There has also been described a method for inserting an i-layer between the n-layer and the p-layer, however, since the purpose of the method is to improve the quality of an interface, a film thickness sufficient to share a load of the optical absorption has not been ensured.

It is therefore an object of the invention to solve the problem that a minority of carriers in an optical absorption layer have a short lifetime to thereby realize reduction in current loss.

The above and other objects, novel features and advantages of the present invention will be apparent from the following detained description of the embodiments of the invention in conjunction with the accompanying drawings.

### Solution to Problem

Representative embodiments of the invention, disclosed in this application, are briefly described as follows.

Firstly, there is provided a solar cell comprising a first p-layer, a first n-layer, a first i-layer provided between the first p-layer and the first n-layer, a second p-layer, a second n-layer, a second i-layer provided between the second p-layer and second n-layer, a first insulating film provided between the first p-layer and the second n-layer, a first through-electrode connected to the first p-layer via a p-layer different from the first p-layer to be connected to the second p-layer, and a second through-electrode connected to the first n-layer via a n-layer different from the first n-layer to be connected to the second n-layer. A film thickness of the first i-layer is larger than that of the first p-layer, and that of the first n-layer, respectively, while a film thickness of the second i-layer is larger than that of the second p-layer, and that of the second n-layer, respectively.

Secondly, there is provided a solar cell comprising a first p-layer, a first n-layer, a first i-layer provided between the first p-layer and the first n-layer, a second p-layer, a second n-layer, a second i-layer provided between the second p-layer and second n-layer, a first insulating film provided between the first p-layer and the second n-layer, a first through-electrode penetrating through the first p-layer, the first n-layer, the first-layer, the second p-layer, the second n-layer, the second i-layer, and the insulating film, and a second through-electrode penetrating through the first p-layer, the first n-layer, the first i-layer, the second p-layer, the second n-layer, the second i-layer, and the insulating film, the second through-electrode differing in Fermi level from the first through-electrode. A film thickness of the first i-layer is larger than that of the first p-layer, and that of the first n-layer, respectively, while a film thickness of the second i-layer is larger than that of the second p-layer, and that of the second n-layer, respectively.

### Advantageous Effects of Invention

According to the present invention, it is possible to strike a good balance between optical absorption and reduction in current loss in a solar cell.

### BRIEF DESCRIPTION OF DRAWINGS

FIG. 1 is a sectional view showing a configuration of a solar cell according to a first embodiment of the invention.

FIG. 2 is a back-surface view showing the configuration of the solar cell according to the first embodiment of the invention.

FIG. 3 (a) is a first sectional view showing a method for manufacturing the solar cell according to the first embodiment of the invention.

FIG. 3 (b) is a second sectional view showing the method for manufacturing the solar cell according to the first embodiment of the invention.

FIG. 3 (c) is a third sectional view showing the method for manufacturing the solar cell according to the first embodiment of the invention.

FIG. 3 (d) is a fourth sectional view showing the method for manufacturing the solar cell according to the first embodiment of the invention.

FIG. 3 (e) is a fifth sectional view showing the method for manufacturing the solar cell according to the first embodiment of the invention.

FIG. 3 (f) is a sixth sectional view showing the method for manufacturing the solar cell according to the first embodiment of the invention.

FIG. 4 is a sectional view showing a configuration of a solar cell according to a second embodiment of the invention.

FIG. 5 is a sectional view showing a configuration of a solar cell according to a third embodiment of the invention.

FIG. 6 is a sectional view showing a configuration of a solar cell according to a fourth embodiment of the invention.

FIG. 7 is a sectional view showing a configuration of a solar cell according to a fifth embodiment of the invention.

FIG. 8 is a sectional view showing a configuration of a solar cell according to a sixth embodiment of the invention.

FIG. 9 is a sectional view showing a configuration of a solar cell according to a seventh embodiment of the invention.

### DESCRIPTION OF EMBODIMENTS

### First Embodiment

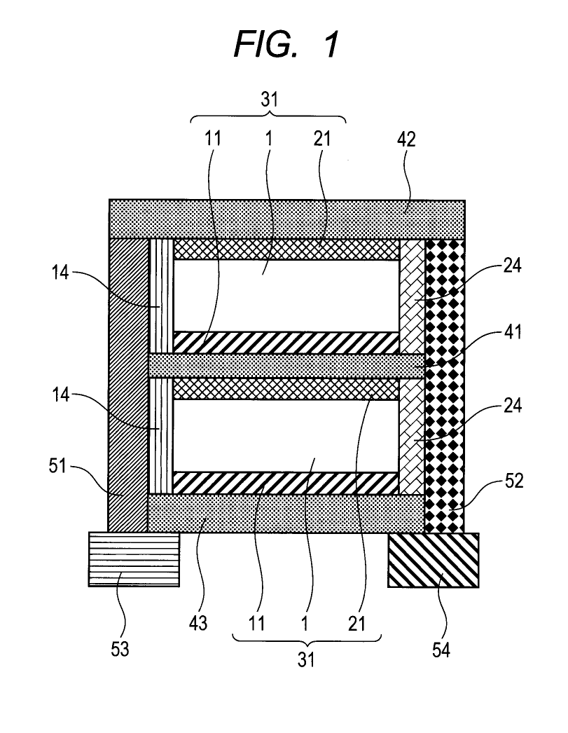

FIG. 1 is a schematic sectional view showing a structure of a solar cell according to a first embodiment of the invention. A common solar cell includes only a single pn junction or a single p-i-n junction, whereas the solar cell according to the present invention has a structure where plural p-i-n junctions 31 are stacked. Herein, it is to be pointed out that for the purpose of obtaining an effect described later in the present description, an i-layer 1 of the p-i-n junction 31 has a film thickness larger than that of a p-layer 11, and that of an n-layer 21, respectively, which is a feature of the solar cell according to the present invention. An insulating film 41 is interposed between the p-i-n junctions 31, adjacent to each other. Further, there are provided through-electrodes penetrating through these p-i-n junctions 31 that are stacked each other, and the p-i-n junctions 31 are electrically connected in parallel with each other though the intermediary of the through-electrodes. As shown in FIG. 1, a through-hole side-face p-layer 14, and a through-hole side-face n-layer 24, provided in such a way as to penetrate through the p-layer 11, the i-layer 1, and the n-layer 21, respectively, are formed on respective through-hole side faces. Accordingly, a p-layer, and an n-layer, in a shape resembling a hook, respectively, are formed around the i-layer 1. As a result, an electron, and a hole, generated due to optical absorption in the i-layer 1, are caused to move in respective directions opposite from each other by the agency of self-contained electric fields generated by the p-layer, and the n-layer, in the hook-like shape, respectively. More specifically, the electron moves from the i-layer 1 to the n-layer 21 before further moving to the through-hole side-face n-layer 24 while the hole moves from the i-layer 1 to the p-layer 11 before further moving to the through-hole side face p-layer 14. The through-hole side face p-layer 14, and the through-hole side face n-layer 24 are electrically connected to the respective through-electrodes. The through-electrode is classified into two types depending on whether the through-electrode is adjacent to the through-hole side face p-layer 14 or the through-hole side face n-layer 24, whereupon the two types each are referred to as a p-layer side through-electrode 51 or an n-layer side through-electrode 52. Electrodes are provided on the top surface, or the back surface of the solar cell, and the electrodes are electrically connected to the through-electrodes, respectively, whereupon the electrode in contact with the p-layer side through-electrode 51 is referred to as a p-layer side electrode 53 while the electrode in contact with the n-layer side through-electrode 52 is referred to as an n-layer side electrode 54. In FIG. 1, there is shown an example where both the p-layer side electrode 53 and the n-layer side electrode 54 are disposed on the back surface of the solar cell, however, both the p-layer side electrode 53 and the n-layer side electrode 54 may be disposed on the top surface, or one of the p-layer side electrode 53 and the n-layer side electrode 54 may be disposed on the top surface while the other thereof may be disposed on the back surface. Regions in the top surface, and the back surface of the solar cell, respectively, without the electrode being in presence, are covered with a top surface insulating film 42 or a back face insulating film 43. Further, in FIG. 1, all the layers are depicted as a flat film, however, a treatment for rough-textured surface may be applied thereto for the purposes of effecting reduction in reflection, and optical confinement. Further, an antireflection film may be added to the top of the surface insulating film 42.

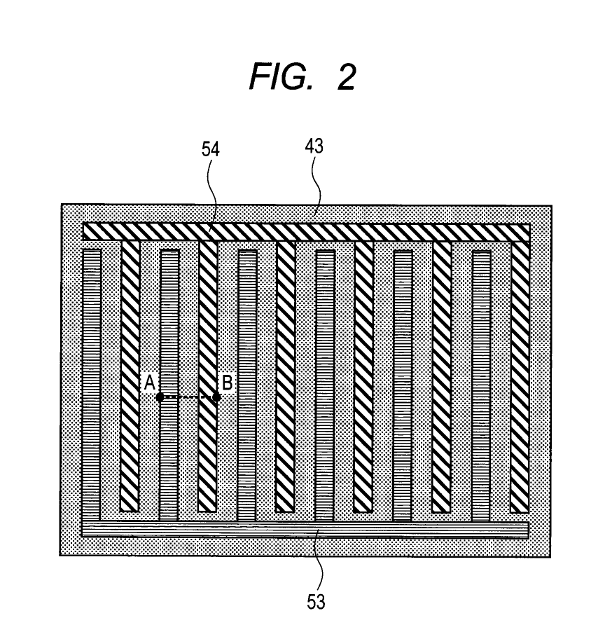

FIG. 2 is a schematic representation of the structure of the solar cell according to the first embodiment of the invention, as seen from the back surface thereof. The p-layer side electrode 53 and the n-layer side electrode 54 are each formed in a comb-like shape, serving as a contact with each of external electrode terminals. A sectional view taken on line A-B of FIG. 2 corresponds to FIG. 1.

Next, there is described hereinafter an operation mechanism of the solar cell according to the present invention. Sunlight incident on the cell is absorbed by any layer of the i-layer 1, the p-layer 11, and the n-layer 21, thereby generating an electron-hole pair. At this point in time, since the present invention has the feature that the film thickness of the i-layer 1 is larger than that of the p-layer 11, and that of the n-layer 21, respectively, as described above, an amount of light absorbed by the i-layer 1 is greater than that absorbed by the p-layer 11, and the n-layer 21, respectively. Accordingly, the i-layer 1 will be a primary spot for generation of the electron-hole pair. The generated electron and hole move to the n-layer 21, and the p-layer 11, respectively, by a drift movement and a diffusion movement, caused by a self-contained electric field of the p-i-n junction 31. The electron that has arrived at the n-layer 21 and the hole that has arrived at the p-layer 11 are caused to move to the n-layer side through-electrode 52, and the p-layer side electrode 53, respectively, by a drift movement and a diffusion movement, caused by respective self-contained electric fields generated by the through-hole side-face p-layer 14, and the through-hole side-face n-layer 24. The electron and the hole, having arrived at the respective electrodes, are caused to move to the n-layer side electrode 54, and the p-layer side electrode 53, respectively, whereupon an output current is generated on the outside. The insulating film 41 interposed between the p-i-n junctions 31, adjacent to each other, not only plays a part in providing electrical insulation between the p-layer 11 of one of the adjacent p-i-n junctions 31, and the n-layer 21 of the other of the adjacent p-i-n junctions 31, but also brings about the effect of interface passivation. Similarly, the top surface insulating film 42 and the back face insulating film 43 each function as a passivation film.

The largest difference between the invention according to Patent Document 1, and the present invention lies in that, with the solar cell described in Patent Document 1, the layer responsible for optical absorption is the n-layer, and the p-layer, respectively, whereas, with the solar cell according to the present invention, the layer primarily responsible for optical absorption is the i-layer 1. In Patent Document 1 as well, there has been described the technique whereby use is made of the p-i-n junction instead of the pn junction; however, the stated purpose of this being enhancement in quality of a p-i-n junction, interface, the i-layer 1 does not, therefore, have a film thickness sufficient to primarily shoulder a responsibility for optical absorption. In contrast, the solar cell according to the present invention has the feature that the film thickness of the i-layer 1 is larger than that of the p-layer 11, and that of the n-layer 21, respectively, as described in the foregoing, and the i-layer 1, therefore, primarily takes on the responsibility for optical absorption.

There is described hereinafter an effect of a difference between the case of optical absorption occurring to the i-layer and the case of optical absorption occurring to either the p-layer, or the n-layer, on the characteristics of the solar cell. In the case where either the p-layer, or the n-layer takes on the responsibility for optical absorption, since an electron generated in the p-layer, and a hole generated in the n-layer are each a minority carrier, both the electron and the hole have a short lifetime, so that there is a high probability of recombination of the electron with the hole before the electron and the hole reach the n-layer and the p-layer, respectively. In contrast, if the i-layer takes on the responsibility for optical absorption, generated electron and hole each have a very long lifetime as compared with a lifetime of a minority carrier, so that there is a high probability that the electron and the hole reach the n-layer, and the p-layer, respectively, without undergoing recombination. Accordingly, a difference between these two methods as described affects the output current of the solar cell, and with the method whereby the i-layer 1 takes on the responsibility for optical absorption, a larger output current can be obtained as compared with the method whereby the p-layer or the n-layer takes on the responsibility for optical absorption.

As described in detail hereinabove, the solar cell according to the present embodiment has the feature in that the solar cell includes a first p-layer 11, a first n-layer 21, a first i-layer 1 provided between the first p-layer 11 and the first n-layer 21, a second p-layer 11, a second n-layer 21, a second i-layer 1 provided between the second p-layer 11 and second n-layer 21, a first insulating film 41 provided between the first p-layer 11 and the second n-layer 21, a first through-electrode 51 connected to the first p-layer via a p-layer different from the first p-layer to be connected to the second p-layer via a p-layer different from the second p-layer to be connected to the second p-layer, and a second through-electrode 52 connected to the first n-layer via a n-layer different from the first n-layer to be connected to the second n-layer via an n-layer different from the second n-layer to be connected to the second n-layer, and a film thickness of the first i-layer is larger than that of the first p-layer, and that of the first n-layer, respectively, while a film thickness of the second i-layer is larger than that of the second p-layer, and that of the second n-layer, respectively. The solar cell having the feature described as above can obtain the following effects.

First, by connecting the first through-electrode to the first p-layer via “a p-layer different from the first p-layer” to be connected to the second p-layer via “a p-layer different from the second p-layer” to be connected to the second p-layer, the p-layer, in the shape resembling the hook, can be formed around the i-layer 1. As for the n-layers, by similarly connecting the second through-electrode to the first n-layer via “a n-layer different from the first n-layer” to be connected to the second n-layer, the n-layer, in the shape resembling the hook, can be formed around the i-layer 1.

As the result, the electron and the hole, generated due to optical absorption in the i-layer 1, can be caused to move in the respective directions opposite from each other by the agency of the self-contained electric fields generated by the p-layer, and the n-layer, in the shape resembling the hook, respectively.

Further, since the film thickness of the first i-layer is larger than that of the first p-layer, and that of the first n-layer, respectively, and the film thickness of the second i-layer is larger than that of the second p-layer, and that of the second n-layer, respectively, a larger output current can be obtained as compared with the case where the p-layer or the n-layer takes on the responsibility for optical absorption.

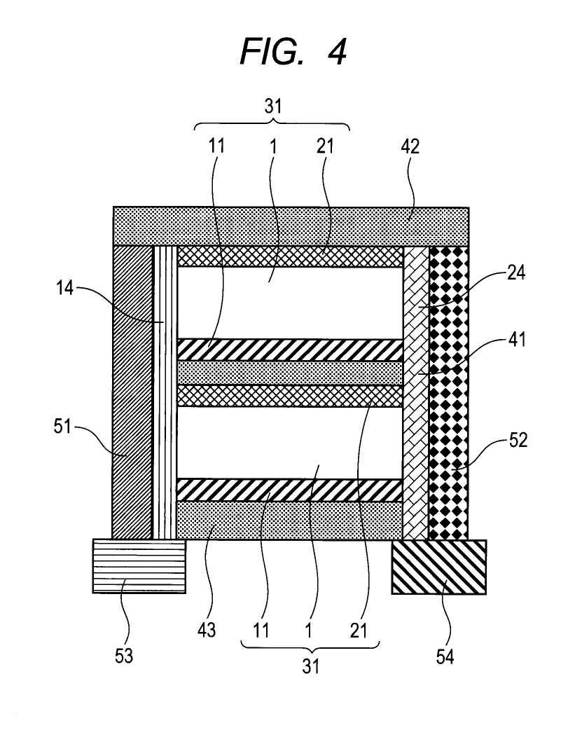

Herein, in reference to “a p-layer different from the first p-layer” and “a p-layer different from the second p-layer”, two structures are assumed. More specifically, the two structures include a structure in which “a p-layer different from the first p-layer” and “a p-layer different from the second p-layer” each make up the p-layer 14 that is independent through the intermediary of the insulating film 41, as shown in FIG. 1, and another structure in which “a p-layer different from the first p-layer” and “a p-layer different from the second p-layer” make up the p-layer 14 that is integrally formed without the insulating film 41 interposed therebetween, as shown in FIG. 4 referred to later. In comparison of the structure of FIG. 1 with the structure of FIG. 4 referred to later, the structure of FIG. 1 has a point in its favor in that because “a p-layer different from the first p-layer” and “a p-layer different from the second p-layer” are electrically isolated from each other, even if a defect is present in one of the p-layers, the other of the p-layers will not be affected. The technical concept of the applicant's invention incorporates both these two structures.

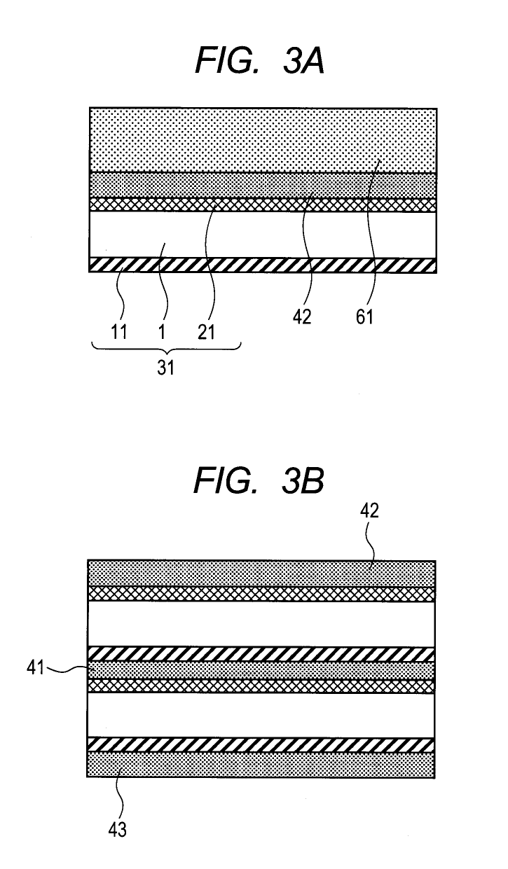

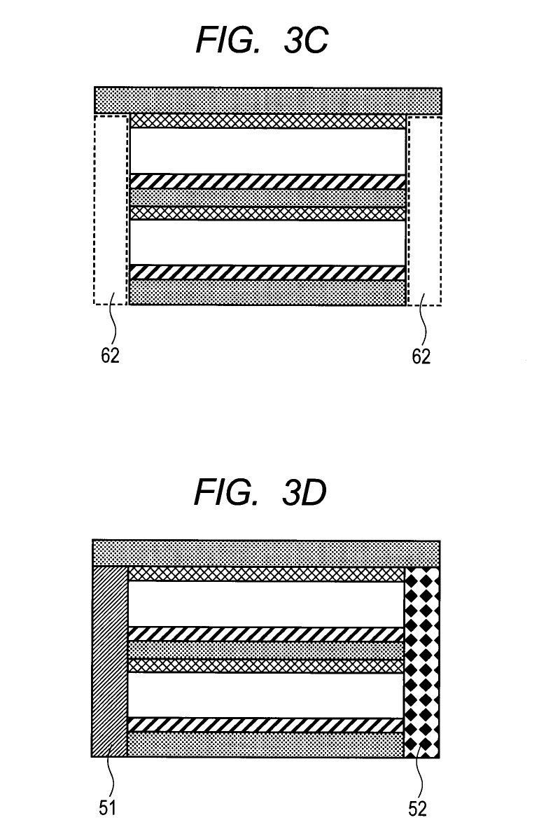

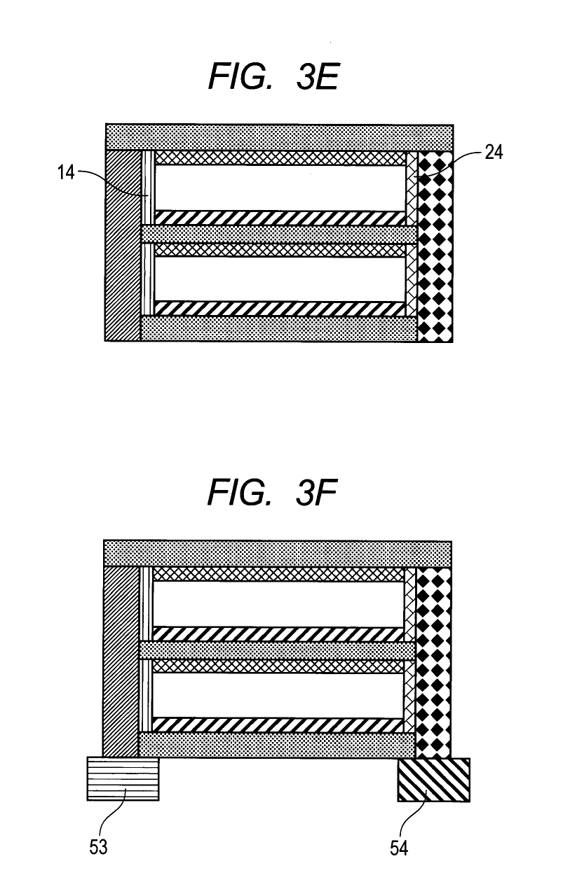

FIG. 3 is a view showing a method for manufacturing the solar cell according to the first embodiment. There are described hereinafter constituent materials of the solar cell according to the invention, and the method for manufacturing the solar cell with reference to FIG. 3.

First, films in a range of from the top surface insulating film 42 to the back face insulating film 43 are formed on a substrate 61. There is no particular limitation to a constituent material of the substrate 61, and use can be made of a substrate such as, for example, an Si-substrate, a quartz substrate, a glass substrate, and so forth. FIG. 3 shows one example of the manufacturing method in the case where the substrate 61 is transparent, and both the p-layer side electrode 53 and the n-layer side electrode 54 are mounted on a side of the cell, adjacent to the back surface thereof. In this case, the top surface insulating film 42 is first formed on the substrate 61, as shown in FIG. 3 (a). The manufacturing method is varied depending on a type of the substrate 61, and whether the electrodes are disposed on a side of the cell, adjacent to the top surface, or a side of the cell, adjacent to the back surface. For example, unless the substrate 61 is transparent, the substrate 61 is preferably not on the side of the solar cell, adjacent to the top surface, in the final structure of the solar cell. For this reason, it is necessary to adopt either of methods, that is, a method of forming the films in sequence on the substrate 61 by starting from the back face insulating film 43, or a method of forming the films in sequence on the substrate 61 by starting from the top surface insulating film 42 to finally cut off the substrate 61. In FIGS. 3 (b) to 3 (f), the substrate 61 is not shown.

Thereafter, there are formed the plural p-i-n junctions 31 in such a state as stacked through the intermediary of the insulating film 41, as shown in FIG. 3 (b). There is no particular limitation to a semiconductor material for use in forming the p-i-n junction 31 of the solar cell. The semiconductor material includes, for example, Si, CdTe, CuInGaSe, InP, GaAs, Ge, and so forth, and can be in various structures such as a single crystal, polycrystal, crystallite, amorphous state, and so forth. These semiconductor layers are formed by a film-forming method such as a CVD method, a sputtering method, an epitaxial method, a vapor deposition method, and so forth. For the constituent material of the insulating film 41, use may be made of a chemical compound of any selected from among the semiconductor materials described, such as SiO₂, SiN (silicon nitride), and so forth, or other insulators. The insulating film 41 can be formed by the film-forming method such as the CVD method, sputtering method, epitaxial method, vapor deposition method, and so forth. Further, if the insulator is a compound of a semiconductor material, the insulating film 41 can be formed by causing any of those semiconductor layers to undergo oxidation, nitriding, and so forth.

Thereafter, through-holes 62 are formed, as shown in FIG. 3 (c). The through-holes 62 each are formed by techniques for using a laser, photolithography, etching, and so forth. In the case where either the p-layer side electrode 53 or the n-layer side electrode 54 is disposed on the side of the cell, adjacent to the back surface thereof, the respective through-holes need penetrate the films from at least the back face insulating film 43 up to the p-i-n junction 31 directly underneath the top surface insulating film 42, however, the respective through-holes may further penetrate through the top surface insulating film 42, and the substrate 61. In the case of forming the respective through-holes 62 by use of a laser, there is available a method whereby a film acting as a barrier against penetration is used as the top surface insulating film 42 in order to prevent penetration through the substrate 61. There is available, for example, a method whereby a two-layer structure is adopted for the top surface insulating film 42, thereby using SiN (silicon nitride) as the film in contact with the substrate 61, while using SiO₂ as the film in contact with the p-i-n junction 31. With this method, since an SiO₂ film is a film low in heat conductivity, even if the p-i-n junction 31 deposited under the substrate 61 is heated by the laser, heat conduction to the substrate 61 will be inhibited. Further, in the case where the semiconductor material for use in forming the p-i-n junction 31 is Si, use of SiO₂ for the passivation film will enable a low interface state density to be realized as compared with the case of using SiN for the passivation film. SiN plays a role in inhibiting impurities contained in the substrate 61 from diffusion into the p-i-n junction 31. With the use of this layered-structure, it is possible to concurrently realize three points, that is, prevention of the through-holes from being formed in the substrate 61, excellent interface passivation, and prevention of the impurities in the substrate 61 from being diffused. Furthermore, the through-hole is preferably formed in an evacuated space in order to prevent burrs from being generated at the time of forming the through-hole.

Thereafter, the p-layer side through-electrode 51 and the n-layer side through-electrode 52 are formed, as shown in FIG. 3 (d). The respective through-electrodes are formed by the film-forming method such as the sputtering method, vapor deposition method, CVD method, and so forth, or by a printing method. For the constituent material of the through-electrode, use is made of a metal, or a heavily doped semiconductor in order to lower electrical resistance. In order that the through-hole side face p-layer 14, and the through-hole side face n-layer 24 are each formed through impurity diffusion, as described later, the p-layer side through-electrode 51, and the n-layer side through-electrode 52 each need contain an element serving as an acceptor, or a donor. Further, if the through-electrode is made of a metal, the constituent material of the p-layer side through-electrode 51 preferably has a work function smaller in value than the work function of the n-layer side through-electrode 52, and if the through-electrode is made of the semiconductor, a p-type semiconductor is preferably used for the p-layer side through-electrode 51 while an n-type semiconductor is preferably used for the n-layer side through-electrode 52. By so doing, it is possible to increase the respective self-contained electric fields for causing the electron, and the hole; generated due to optical absorption in the i-layer 1, having subsequently arrived at the n-layer 21, and the p-layer 11, respectively, to undergo drift movement to the n-layer side through-electrode 52, and the p-layer side through-electrode 51, respectively.

Subsequently, a heat treatment for electrode baking is carried out, whereupon the acceptor, and the donor, contained in the through-electrode, are diffused into the p-i-n junction 31 by concurrent, or continuous applications of the heat treatment, thereby forming the through-hole side-face p-layer 14, and the through-hole side-face n-layer 24, as shown in FIG. 3 (e).

Further, with the first embodiment of the invention, the through-electrodes are formed before the through-hole side-face p-layer, and the through-hole side-face n-layer are formed, however, the through-hole side-face p-layer, and the through-hole side-face n-layer may be formed by an impurity diffusion method, such as ion-implantation, a vapor-phase diffusion method, a solid diffusion method, and so forth, before formation of the through-electrodes, and thereafter, the through-electrodes may be formed. In this case, an acceptor or a donor need not be contained in the constituent material of the through-electrode.

The electrodes are formed concurrently with the formation of the through-electrodes, or additionally formed after the formation of the through-electrodes, as shown in FIG. 3 (f). For the constituent material of the electrode, use is preferably made of a metal low in electrical resistance. The constituent material of the p-layer side electrode 53 may be identical in species to that of the n-layer side electrode 54, or may differ in species from that of the n-layer side electrode 54. The electrodes are formed generally by a printing method, however, may be formed by a film-forming method such as the sputtering method, the vapor deposition method, the CVD method, and so forth. The electrode can have any suitable width, however, in the case where the electrodes are formed on the side of the solar cell, adjacent to the top surface thereof, an optimum electrode-width need be decided upon by taking into consideration a loss due to shading by the electrodes, and the electrical resistance of the electrodes. In the case where the electrodes are formed on the side of the solar cell, adjacent to the back surface thereof, an electrode-width is increased as much as possible within a scope posing no risk of the p-layer side electrode 53 coming into contact with the n-layer side electrode 54, thereby causing a short circuit, whereupon it is possible to concurrently realize reduction in the electrical resistance of the electrode, and enhancement in reflectance of incident light on the back surface of the cell. In FIG. 2, the electrode extended in the longitudinal direction may differ in respect of the constituent material of the electrode, and the electrode-width from the electrode extended in the transverse direction.

In addition to steps described as above, there may be added steps as appropriate, the steps including a heat treatment for improvement in crystallinity of the respective films, and improvement in film quality, or improvement in quality of an interface between the films adjacent to each other, a plasma treatment, and so forth.

### Second Embodiment

FIG. 4 is a schematic sectional view showing a structure of a solar cell according to a second embodiment of the invention. This structure has a feature in that portions of the through-hole side-face p-layer 14, connected to the respective p-i-n junctions 31 as well as portions of the through-hole side face n-layer 24, connected to the respective p-i-n junctions 31, in the case of the solar cell according to the first embodiment, are not electrically isolated from each other by the insulating film 41.

With the second embodiment of the invention, a contact area between the through-hole side-face p-layer 14, and both the p-layer side through-electrode 51, and p-layer side electrode 53, and a contact area between the through-hole side-face n-layer 24, and both the n-layer side through-electrode 52, and the n-layer side electrode 54 can be enlarged as compared with the case of the first embodiment, so that contact resistance at those contact parts described can be reduced. Further, the operating principles of the solar cell according to the second embodiment are the same as that for the first embodiment, and the electron, and the hole, generated due to optical absorption in the i-layer 1, are caused to move in the respective directions opposite from each other, thereby causing an output current to be generated.

For fabrication of a structure according to the second embodiment of the invention, it need only be sufficient to form the through-hole side-face p-layer 14, and the through-hole side-face n-layer 24 by the film-forming method, such as the CVD method, sputtering method, epitaxial method, vapor deposition method, and so forth, prior to a step for forming the through-electrodes, among the steps of fabricating the structure according to the first embodiment.

In comparison of the structure according to the second embodiment with the structure according to the first embodiment, the structure according to the second embodiment has a point in its favor in that it is possible to omit a step among the steps of fabricating the structure according to the first embodiment, the step being for making use of respective portions of the p-layer 11, and the n-layer 21 for the respective portions of the through-hole side-face n-layer 24, and the through-hole side-face p-layer 14, through impurity diffusion. In order to carry out impurity diffusion whereby a p-type and an n-type are each reversed in polarity, it is generally necessary to cause diffusion of an impurity in reversed polarity, in concentration exceeding an original impurity concentration. Accordingly, with the second embodiment, there occur no constraint condition concerning a relationship in magnitude of impurity concentration between the p-layer 11 and the through-hole side-face n-layer 24 as well as between the n-layer 21 and the through-hole side-face p-layer 14. Further, with the second embodiment of the invention, since the through-hole side-face n-layer 24, and the through-hole side-face p-layer 14 are formed by the film-forming method, the respective film-thicknesses of these layers can be increased with greater ease as compared with the case of the first embodiment. As a result, the structure according to the second embodiment has an advantage in that excellent rectifying property can be realized at pn junctions formed between the through-hole side-face n-layer 24 and the through-hole side-face p-layer 14, and pn junctions formed between the n-layer 21 and the p-layer 11 within the p-i-n junction.

### Third Embodiment

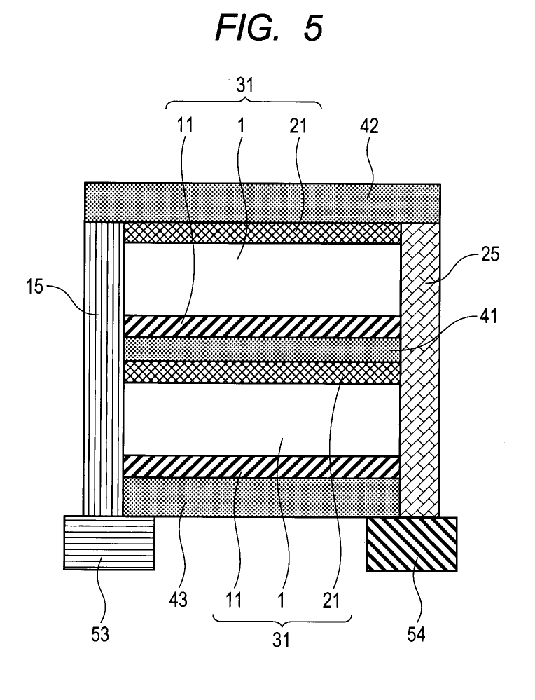

FIG. 5 is a schematic sectional view showing a structure of a solar cell according to a third embodiment of the invention. This structure has a feature in that the through-hole side-face p-layer 14, and the through-hole side-face n-layer 24 are not provided as compared with the case of the solar cell according to the first embodiment, and for through-electrodes, use is made of metals, or semiconductors, differing in Fermi level from each other. More specifically, a through-hole p-type electrode 15 is formed of a material lower in Fermi level, and a through-hole n-type electrode 25 is formed of a material higher in Fermi level, respectively.

According to the third embodiment, it is possible to omit a step among the steps of fabricating the structure according to the first embodiment, the step being for the heat treatment required by the impurity diffusion, necessary for the formation of the through-hole side face p-layer 14, and the through-hole side face n-layer 24. By so doing, a material susceptible to degradation in electrical or optical properties, due to the heat treatment, can be used as the constituent material of the layers, such as the p-i-n junction 31 and so forth, to be formed prior to the heat treatment. Further, since the operating principles of the solar cell according to the third embodiment are the same as that for the first embodiment, and the through-hole p-type electrode 15 differs in Fermi level from the through-hole n-type electrode 25, an electron, and a hole, generated due to optical absorption in an i-layer 1, are caused to move in respective directions opposite from each other, thereby generating an output current.

For fabrication of a structure according to the third embodiment of the invention, it need only be sufficient to form the through-hole p-type electrode 15, and the through-hole n-type electrode 25 by making use of metals, or semiconductors, differing in Fermi level from each other for an constituent material of the electrode in the step of forming the through-electrodes, among the steps of fabricating the structure according to the first embodiment. The third embodiment of the invention has an advantage in that the heat treatment necessary for the formation of the through-hole side face p-layer 14, and the through-hole side face n-layer 24 is no longer required, as described in the foregoing.

### Fourth Embodiment

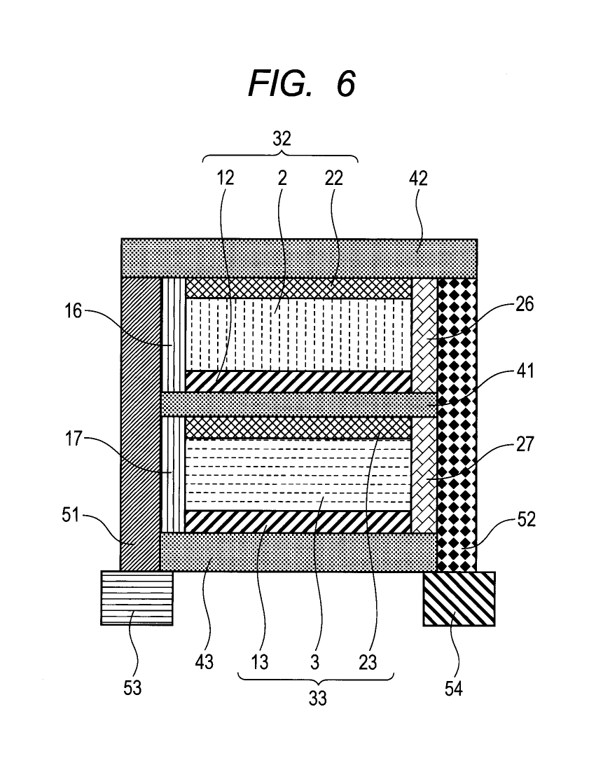

FIG. 6 is a schematic view showing a structure of a solar cell according to a fourth embodiment of the invention. This structure has a feature in that for semiconductor materials making up the p-i-n junctions 31 stacked in the solar cell according to the first embodiment, use is made of a plurality of substances differing in bandgap from each other instead of a single substance. A sequence of stacked layers is set such that the greater the bandgap of a substance is, the closer to an incidence plane of sunlight a layer of the substance is disposed. It is unnecessary that the number of the stacked layers be in agreement with the number of substance species. That is, a plurality of layers made of a single species substance may be present. Further, such a variation as described above may be applied to the second embodiment, and the third embodiment instead of the first embodiment.

The solar cell according to the fourth embodiment exhibit the following optical absorption characteristics under a bandgap condition described as above: the number of the stacked layers of the p-i-n junctions 31 is expressed as T, respective bandgaps (Eg) of constituent substances of respective layers are expressed as Eg 1, Eg 2, . . . , Eg T. According to the sequence of the stacked layers, described as above, the following expression holds.

Eg1≧Eg2≧ . . . ≧EgT.

If light energy is expressed as EL, light meeting a condition EL≧Eg 1 is absorbed by a first p-i-n junction 32 from a device surface, and light meeting a condition EL≧Eg 2 in a portion of light, not absorbed by the first p-i-n junction 32, is absorbed by a second p-i-n junction 33 from the device surface. The same can be said of a third p-i-n junction from the device surface, and onwards.

With the fourth embodiment of the invention, it is possible to concurrently realize all three points including absorption in a wide wavelength range of the solar cell, inhibition of hot carrier generation, and reduction of variation in output current. Before exhibiting the above, these three points are briefly described hereinafter. First, sunlight contains light components in a wide wavelength range, and techniques for absorbing the light components in such a wide wavelength range as much as possible are required for enhancement in efficiency of the solar cell. Then, as for the inhibition in the generation of the hot carriers, a part of a portion of light energy meeting the optical absorption characteristics described, representing EL minus Eg, is given to an electron, and a hole, respectively, as excess energy. Such a carrier as the electron, or the hole is higher in energy state than a conduction band edge, or a valence band edge, being called a hot carrier. In the solar cell, the excess energy of the hot carrier is normally dissipated in the form of heat before reaching the electrode. This heat that is not taken out is not only useless but also heats up the semiconductor materials of the cell, thereby causing deterioration in properties of the cell. More specifically, as the result of a Fermi level in a doped semiconductor, approaching the intrinsic level, due to a rise in temperature, an output voltage of the solar cell drops along with the rise in temperature. Besides the above, temperature has many effects on the properties of the solar cell, including a rise in carrier scattering probability due to the rise in temperature. Accordingly, how to inhibit generation of hot carriers is important from the viewpoint of enhancement in the properties of the solar cell. Lastly, as for the variation in output current, this point is important with respect to the properties of a module made up of cells connected in series rather than with respect to the properties of a solar cell unit. If the respective cells have variation in output current, the output current of the module will be reduced by the variation because the output current of the module will match the minimum value of the output current. Techniques for reducing variation in output current are therefore required for enhancement in efficiency of the module.

Next, there is described hereinafter how the problems described in the foregoing can be, in fact, solved by adoption of the structure of the solar cell according to the fourth embodiment of the invention. For the sake of explanation, the following three examples are taken into consideration as comparison targets. A first example represents the case where, in the structure of the solar cell according to the first embodiment, all the p-i-n junctions are each made up of a substance having a bandgap corresponding to a side of a sunlight spectrum, adjacent to a relatively long wavelength. A second example represents the case where, in the structure of the solar cell according to the first embodiment, all the p-i-n junctions are each made up of a substance having a bandgap corresponding to a side of the sunlight spectrum, adjacent to a relatively short wavelength. A third example is the case of a structure of the so-called tandem solar cell, representing a solar cell structure where a plurality of pn junctions or a plurality of p-i-n junctions are connected in series.

First, the first example is compared with the fourth embodiment of the invention. There exists a difference therebetween in that the inhibition of hot carrier generation can be realized only in the case of the fourth embodiment. The reason for this is because the respective constituent substances of all the p-i-n junctions are relatively small in bandgap in the case of the first example, and therefore, the hot carrier generation, caused by a short wavelength component of the sunlight, is unavoidable.

Then, the second example is compared with the fourth embodiment of the invention. There exists a difference therebetween in that the absorption in the wide wave-range can be realized only in the case of the fourth embodiment. The reason for this is because the respective constituent substances of all the p-i-n junctions in the case of the second example are relatively large in bandgap in the case of the second example, and therefore, a long wavelength component of the sunlight cannot be absorbed

Lastly, the third example is compared with the fourth embodiment of the invention. There exists a difference therebetween in that the reduction of variation in the output current can be realized only in the case of the fourth embodiment. The reason for this is described hereinafter. Firstly, in the case where optical absorption in a layer of the stacked pn junctions or the stacked p-i-n junctions differs from that at the time of designing due to a deviation in film thickness or film composition as a point in common with the third example, and the fourth embodiment, other layer can compensate for the optical absorption. However, with the third example, since the plural pn junctions or the plural p-i-n junctions are connected in series, variation in output current of an individual pn junction or an individual p-i-n junction, as it is, will represent variation in the total output current of the solar cell. Accordingly, in the case of the third example, even if the optical absorption is compensated for, it is not possible to compensate for the variation in the total output current. In contrast, with the fourth embodiment, since the pn junctions or the p-i-n junctions are parallel connected, the total output current is the sum of the respective output currents of the p-i-n junctions. For this reason, even if variation exists in the output current of each of the p-i-n junctions, due to variation in optical absorption, the variation in the total output current can be compensated for. In contrast to the three examples considered as the comparison targets described as above, the fourth embodiment can therefore concurrently realize all those points including the absorption in the wide wavelength range, the inhibition of hot carrier generation, and the reduction of variation in output current.

For fabrication of a structure according to the fourth embodiment of the invention, it need only be sufficient to form as appropriate the layers differing in bandgap from each other, as described in the foregoing, at the time of forming the p-i-n junction 31 among the steps of fabricating the structure according to the first embodiment. For the substances differing in bandgap from each other, use can be made of substances differing in elemental composition, substances identical in composition to each other, but differing in crystalline state from each other, substances identical in both composition and crystalline state to each other, but differing in bandgap from each other owing to a quantum confined effect described hereunder in a fifth embodiment of the invention, and so forth.

### Fifth Embodiment

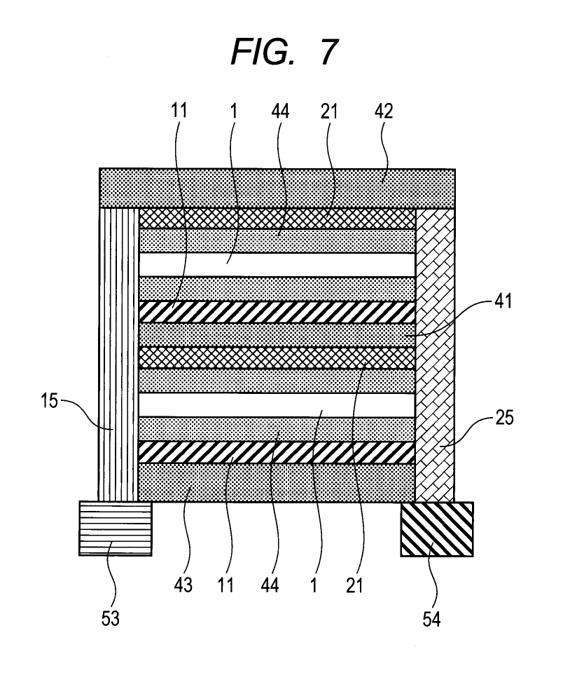

FIG. 7 is a schematic view showing a structure of a solar cell according to a fifth embodiment of the invention. This structure has a feature in that the optical absorption layer in the solar cell according to the third embodiment is not the single i-layer 1, but includes a three-layer stacked structure having an i-layer 1 sandwiched between insulating films 44 disposed over, and underneath the i-layer 1, respectively. A requirement for the insulating films 44 is for the films to serve as a barrier film for forming an energy barrier against both an electron and a hole, in the i-layer 1. The insulating film 44 is hereinafter referred to as a barrier film 44. If the i-layer 1 is made of, for example, Si, for the barrier film 44, use can be made of SiO₂, SiN (silicon nitride), SiC (silicon carbide), and so forth. At this point in time, it is important to set such that a film thickness of the i-layer 1 is caused to be sufficiently small, and the bandgap of the layer has a value different from a value of the bandgap of a bulk substance, that is, the so-called quantum confined effect is generated. More specifically, a film thickness for generating the quantum confined effect is on the order of an effective Bohr radius “a” of an exciton, a=(1/mₑ+1/mₕ)×(∈h²)/(πe²), as a guide, where “mₑ”, and “mₕ” each express an effective mass of an electron, and an effective mass of a hole, respectively, “∈” expresses dielectric constant, “h” expresses Planck constant, and “e” expresses an elementary electric charge. Expression described as above is based on the MKSA unit system. Further, a requirement for generation of the quantum confined effect depends on a height of the energy barrier formed by the barrier film 44, and a film thickness of the barrier film 44 besides the film thickness of a film where the quantum confined effect is generated, that is, the i-layer 1 in this case. In order to quantitatively find dependence, it is necessary to solve Schrodinger equation, however, there is a tendency that the lower the energy barrier formed by the barrier film 44 qualitatively turns, and the smaller the film thickness of the barrier film 44 qualitatively turns, the further inhibited is the quantum confined effect, so that the bandgap will be closer to the bandgap of the bulk substance. Accordingly, in order to obtain a desired bandgap, it is important to select the height of the energy barrier formed by the barrier film 44, and the film thickness of the barrier film 44. In general, a change in bandgap from the bandgap of the bulk substance, owing to the quantum confined effect, is continuous, and the smaller the film thickness is, the greater the change is. By taking advantage of this, the film thickness of the i-layer 1 in the p-i-n junctions 31 to be stacked is varied in value on a layer-by-layer basis, and by so doing, it is also possible to fabricate the structure according to the fourth embodiment. Further, with the fifth embodiment of the invention, there is described a structure where the quantum confined effect is expressed by taking a structure with a thin film sandwiched between the insulating films, the so-called quantum well, as an example. However, the contents of the fifth embodiment are also applicable to a structure differing in confinement dimension, such as a quantum wire, a quantum dot, and so forth. Further, a variation described as above may be applied to the respective solar cells according to the first embodiment, and the second embodiment instead of the solar cell according to the third embodiment.

First, a problem with a related art technology is described hereinafter in order to clarify the effect of the solar cell according to the fifth embodiment of the invention. Hopes run high that a solar cell capable of absorbing light components in a wide wavelength range will be realized by combining the solar cell made up of substances, respective bandgaps thereof being modulated by virtue of the quantum confined effect with the solar cell made up of the bulk substance. However, in order to cause the quantum confined effect to be expressed, the barrier film 44 as an insulator need be inserted as described above, which brings about an increase in electrical resistance, thereby posing a problem that the output current of the solar cell is significantly reduced. In order to solve the problem, it is necessary to decrease the film thickness of the barrier film through which an electron and a hole pass, however, reduction in the film thickness of the barrier film has thus far been difficult to achieve for the following reason. Firstly, the film thickness of the i-layer 1 to be confined by the barrier films 44 need be small to such an extent as to cause the occurrence of the quantum confined effect. Accordingly, in the case of application of the quantum confined effect to a solar cell, it is a common practice to alternately stack a multitude of the barrier films 44, and the i-layers 1 one after another to thereby increase the total film thickness of the i-layers 1 in order to ensure sufficient optical absorption. However, in consequence of stacking the multitude of the barrier films 44, and the i-layers 1, the total film thickness of the barrier films 44 through which the electron and the hole pass will also increase, resulting in a considerable increase in electrical resistance. Accordingly, in the application of the quantum confined effect to the solar cell, it has thus far been impossible to strike a good balance between ensuring of sufficient optical absorption and reduction in the electrical resistance.

With the fifth embodiment of the invention, it is possible to strike the good balance between the ensuring of sufficient optical absorption and the reduction in the electrical resistance. In order to ensure the sufficient optical absorption, firstly, a multitude of unit structures, the unit structure including a p-layer 11-optical absorption layer-n-layer 21, are stacked one after another to thereby increase the total film thickness of the i-layers 1. Herein, with the fifth embodiment of the invention, since the structure including the barrier films 44 is positioned at a spot where the p-i-n junction 31 is present in the case of the first embodiment of the invention, the spot is more commonly denoted as a p-layer 11-optical absorption layer-n-layer 21. A point of importance lies in that, in the case of the related art technology, the multitude of the barrier films 44, and the i-layers 1 are alternately stacked one after another, that is, a multitude of the optical absorption layers only are stacked, whereas, with the present embodiment, the structure having the optical absorption layer sandwiched between the p-layer 11 and the n-layer 21 is adopted as the unit structure, and the multitude of the unit structures are stacked one after another. As the result of this, an electron and a hole, generated in the optical absorption layer, can reach the p-layer 11 and the n-layer 21, respectively, only after passing through all the multitude of the optical absorption layers that are stacked up in the case of the related technology, whereas, with the fifth embodiment, the electron and the hole can reach the p-layer 11 and the n-layer 21, respectively, only if those carriers pass through a single optical absorption layer in the unit structure. Accordingly, with the fifth embodiment, the total film thickness of the barrier films 44 through which the electron and the hole pass is equal to the film thickness of the barrier film 44 included in the unit structure, so that the output current of the solar cell can be considerably increased as compared with the case of a related art system. Further, with the fifth embodiment, there has been described the case where the i-layer 1 included in the unit structure of the p-layer 11-optical absorption layer-n-layer 21 is one layer, however, the number of the i-layers 1 included in the unit structure is optional. The fewer the number of the stacked layer is, the further the (total) film thickness of the barrier films 44 through which the electron and the hole pass can be reduced, so that the effect of reduction in current loss becomes greater.

For fabrication of the structure according to the fifth embodiment of the invention, it need only be sufficient to substitute the step of forming the three-layer stacked structure for the step of forming the absorption layer among the steps of fabricating the structure according to the third embodiment. The barrier film 44 over the i-layer 1 can be formed by the film-forming method such as the CVD method, sputtering method, epitaxial method, vapor deposition method, and so forth, or by oxidation or nitriding of the i-layer 1. Furthermore, there may be added steps as appropriate, the steps including a heat treatment for improvement in crystallinity as well as film quality of the i-layer 1, or improvement in quality of an interface between the films adjacent to each other, a plasma treatment, and so forth.

### Sixth Embodiment

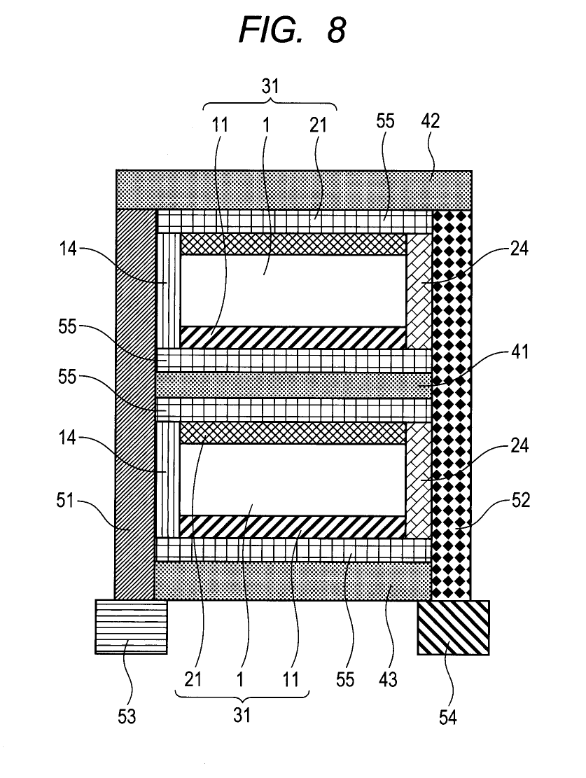

FIG. 8 is a schematic view showing a structure of a solar cell according to a sixth embodiment of the invention. This structure has a feature in that a transparent conductive film 55 is inserted between an insulating film and a p-layer 11 adjacent thereto in each p-i-n junction 31 as well as between the insulating films adjacent to an n-layer 21 in each p-i-n junction 31. The transparent conductive film 55 need have a high sheet resistance as compared with either the p-layer 11 or the n-layer 21, and preferably has a high transmittance in the wavelength range of sunlight. As for the transparent conductive film 55, it is necessary to select film species and film thickness so as to meet these requirements described. Further, a variation described as above may be applied to the respective solar cells according to the second embodiment, and the third embodiment instead of the solar cell according to the first embodiment.

For fabrication of a structure according to the sixth embodiment of the invention, it need only be sufficient to add the step of forming the transparent conductive film 55 to the steps of fabricating the structure according to the first embodiment. As a specific example of the transparent conductive film 55, there is cited an oxide that contains elements including In, Zn, Sn, and Ga, and a complex oxide of those elements. An additive such as fluorine, and so forth may be added thereto. Film-forming is carried out by the sputtering method, the CVD method, the printing method, a coating method, and so forth. Further, for enhancement in quality of the interfaces of the transparent conductive film 55 with the p-layer 11, and the n-layer 21, respectively, another film may be inserted between the transparent conductive film 55 and the p-layer 11 as well as between the transparent conductive film 55 and the n-layer 21, respectively. Furthermore, there may be added steps as appropriate, the steps including a heat treatment, a plasma treatment, and so forth, intended for improvement in crystallinity as well as film quality of the transparent conductive film 55, or improvement in quality of an interface between the films adjacent to each other.

A constituent material of the transparent conductive film 55 is often made up of elements different from those of the constituent semiconductor material of the p-i-n junction 31, and in such a case, it is not possible to use the impurity diffusion method as the method for forming the through-hole side-face p-layers 14, and the through-hole side-face n-layers 24, respectively, as is the case with the first embodiment. Accordingly, in order to generate the self-contained electric fields for causing an electron, and a hole, in the transparent conductive film 55, to move in respective directions opposite from each other, it is necessary to adopt any of methods, the methods including the film-forming method whereby the through-hole side-face p-layer 14, and the through-hole side-face n-layer 24, respectively, are formed, as is the case with the second embodiment, a method for forming the through-hole p-type electrode 15, and the through-hole n-type electrode 25, as is the case with the third embodiment, and a method for generating the self-contained electric fields simply by taking advantage of a difference in work function between the respective constituent metal materials of the through-electrodes, as is the case with the first embodiment.

With the sixth embodiment of the invention, a series resistance component of the solar cell according to the first embodiment can be reduced. The reason for that is because the electron, and the hole, generated due to optical absorption, need to move in the in-plane directions of the p-layer, and the n-layer, respectively, within the p-i-n junction 31, in the case of the first embodiment, whereas, in the case of the sixth embodiment, the electron, and the hole, can move in the in-plane direction of the transparent conductive film 55 lower in sheet resistance than the p-layer, and the n-layer, respectively.

### Seventh Embodiment

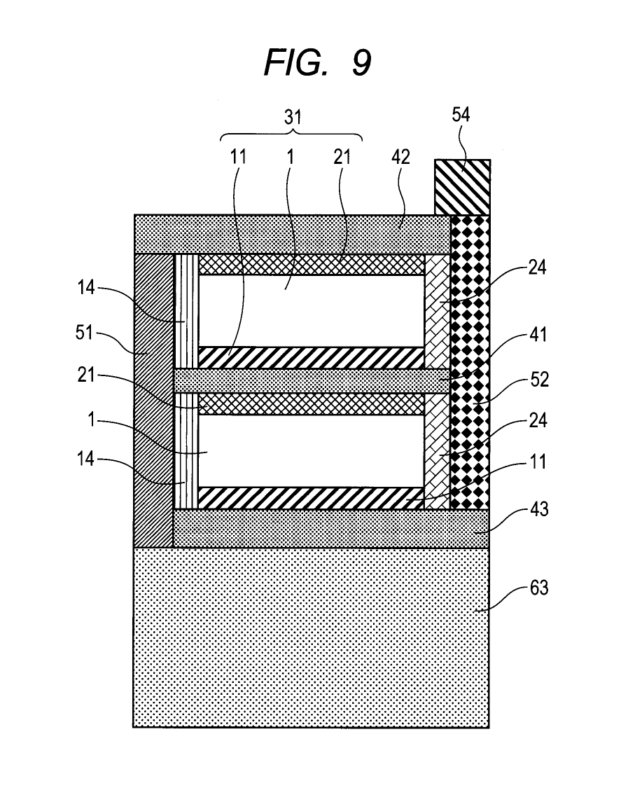

FIG. 9 is a schematic view showing a structure of a solar cell according to a seventh embodiment of the invention. This structure is a tandem structure in which the solar cell according to the first embodiment is connected in series to a conventional type solar cell 63, that is, the cell comprised of only a single pn junction, or a single p-i-n junction. In FIG. 9, a p-layer side electrode is formed on a side of the conventional type solar cell 63, adjacent to the back surface thereof while an n-layer is formed on a side of the conventional type solar cell 63, adjacent to the top surface thereof, and a p-layer side through-electrode 51 of the solar cell according to the present invention is connected to the n-layer while an n-layer side through-electrode 52 of the solar cell according to the present invention is connected to an n-layer side electrode 54 on the top surface of the cell. This structure may be a structure in which these p-layer, and n-layer are disposed so as to be inverted. Further, use may be made of the solar cell according to any of the second to the sixth embodiments of the invention instead of the first embodiment. A tunnel junction diode may be formed at a joint between the conventional type solar cell 63 and the solar cell according to the present invention. The top surface insulating film of the conventional type solar cell 63 is described hereinafter as a film identical to the back face insulating film 43 of the solar cell according to the present invention; however, these film may differ from each other.

With the solar cell according to the seventh embodiment, the sequence of stacked layers in the conventional type solar cell 63 as well as the solar cell according to the present invention is preferably set such that a solar cell made up of a semiconductor material greater in bandgap is placed on the incidence plane side of sunlight, as is the case with a common tandem solar cell. Further, since the solar cell according to the present invention is effective for application to a semiconductor material having a problem of a short carrier lifetime, in particular, the structure of the solar cell according to the present invention is preferably applied to a solar cell comprised of a semiconductor material having a short carrier lifetime, and in the case of the solar cell according to the seventh embodiment as well, a solar cell structure according to the present invention is preferably applied to a solar cell comprised of a semiconductor material having a shorter carrier lifetime.

According to the seventh embodiment of the invention, higher efficiency of the tandem solar cell can be achieved. The effect of enhancement in efficiency is significant in the case of a tandem solar cell fabricated by combining solar cells with each other, the solar cells being comprised of respective semiconductor materials considerably differing in carrier lifetime from each other, in particular. In this connection, there is described hereinafter a problem with the related art technology. In the case of the tandem solar cell, a plurality of solar cells are connected in series to each other, and therefore, values of respective currents flowing through these cells have to match up with each other. Accordingly, if the plural cells differing in output current are arranged in tandem with each other, the minimum value of those output currents will represent the output current of the plural cells in whole. In the past, therefore, a tandem solar cell made up by combining cells with each other, the cells differing in output current from each other, has been often found lower in efficiency as compared with a cell unit of the tandem solar cell, larger in output current. On the other hand, with the solar cell according to the seventh embodiment, the output current thereof can be enhanced by application of the structure of the solar cell according to the present invention to a solar cell small in output current. As a result, the output current of the tandem solar cell in whole can be enhanced as compared with a conventional type tandem solar cell, so that a highly efficient tandem solar cell can be realized.

For fabrication of the structure according to the seventh embodiment of the invention, there are available two methods including a method for forming the conventional type solar cell 63 in advance, and a method for forming the solar cell according to the present invention in advance.

First, there is described the method for forming the conventional type solar cell 63 in advance, subsequently forming the solar cell according to the present invention in accordance with the method shown in the first embodiment of the invention. In this case, setting is made such that the p-layer side through-electrode 51 penetrates through the solar cell according to the present invention from the lower end of a top surface insulating film 42 thereof down to the lower end of a back face insulating film 43 while the n-layer side through-electrode 52 penetrates through the solar cell according to the present invention from the upper end of the top surface insulating film 42 thereof down to the upper end of the back face insulating film 43, as shown in FIG. 9. As a method for forming the p-layer side through-electrode 51, there is available, for example, a method of using a process whereby a through-hole reaching the upper end of the top surface insulating film 42 is formed, the through-hole is filed up with the constituent material of the p-layer side through-electrode 51, and subsequently, the constituent material of the p-layer side through-electrode 51 is fired at a temperature in excess of the melting point of the constituent material for a short period of time, thereby causing the electrode material to penetrate through the back face insulating film 43, that is, the so-called fire-through process. As a method for forming the n-layer side through-electrode 52, there is available, for example, a method whereby the barrier film resistant to laser penetration, as described with reference to the first embodiment, is used as the back face insulating film 43.

The method for forming the solar cell according to the present invention in advance is further classified into two methods, depending on whether or not a transparent material is used for the substrate 61 on which the solar cell according to the present invention is formed. In the case of using a transparent substrate, the sequence of film formation is set such that the transparent substrate is disposed on the topmost surface of the structure of the solar cell in its final stage. At this point in time, the through-hole needs to completely penetrate through the substrate 61 so as to enable the electrode to be disposed to the top surface. On the other hand, in the case where a non-transparent material is used as the substrate 61, it is necessary to add the step of cutting off the substrate 61 from a solar cell formed thereon. As a cut-off method, there are applicable, for example, a smart-cut method as one of methods for forming an SOI (Silicon On Insulator) wafer, and so forth. Further, as a method for forming the conventional type solar cell 63 on the solar cell according to the present invention, two methods are applicable, including a method for forming the layers of the conventional type solar cell 63 by use of the film-forming method such as the CVD method, sputtering method, epitaxial method, vapor deposition method, and so forth, and another method for separately forming the conventional type solar cell 63 to be bonded to the solar cell according to the present invention. The method for forming the SOI wafer is applicable to a bonding method as well.

Having specifically described the invention developed by the inventor, et al. on the basis of the embodiments of the invention as above, it is to be pointed out that the invention be not limited by any of the embodiments, and that various changes and modifications may be made in the invention without departing from the spirit and scope thereof.

### LIST OF REFERENCE SIGNS

1 . . . i-layer, 2 . . . i-layer of a semiconductor substance having a bandgap Eg 1, 3 . . . i-layer of a semiconductor substance having a bandgap Eg 2, 11 . . . p-layer, 12 . . . p-layer of the semiconductor substance having the bandgap Eg 1, 13 . . . p-layer of the semiconductor substance having the bandgap Eg 2, 14 . . . through-hole side-face p-layer, 15 . . . through-hole p-type electrode, 16 . . . through-hole p-type electrode of a solar cell made of the semiconductor substance having the bandgap Eg 1, 17 . . . through-hole p-type electrode of a solar cell made of the semiconductor substance having the bandgap Eg 2, 21 . . . n-layer, 22 . . . n-layer of the semiconductor substance having the bandgap Eg 1, 23 . . . n-layer of the semiconductor substance having the bandgap Eg 2, 24 . . . through-hole side-face n-layer, 25 . . . through-hole n-type electrode, 26 . . . through-hole side-face n-layer of the solar cell made of the semiconductor substance having the bandgap Eg 1, 27 . . . through-hole side-face n-layer of the solar cell made of the semiconductor substance having the bandgap Eg2, 31 . . . p-i-n junction, 32 . . . p-i-n junction of the semiconductor substance having the bandgap Eg 1, 33 . . . p-i-n junction of the semiconductor substance having the bandgap Eg 2, 41 . . . insulating film, 42 . . . top surface insulating film, 43 . . . back face insulating film, 44 . . . barrier film, 51 . . . p-layer side through-electrode, 52 . . . n-layer side through-electrode, 53 . . . p-layer side electrode, 54 . . . n-layer side electrode, 55 . . . transparent conductive film, 61 . . . substrate, 62 . . . through-hole, 63 . . . conventional type solar cell

1. A solar cell comprising:
a first p-layer;
a first n-layer;
a first i-layer provided between the first p-layer and the first n-layer;
a second p-layer;
a second n-layer;
a second i-layer provided between the second p-layer and second n-layer;
a first insulating film provided between the first p-layer and the second n-layer;
a first through-electrode connected to the first p-layer via a p-layer different from the first p-layer to be connected to the second p-layer via a p-layer different from the second p-layer;
a second through-electrode connected to the first n-layer via a n-layer different from the first n-layer to be connected to the second n-layer via an n-layer different from the second n-layer,
wherein a film thickness of the first i-layer is larger than that of the first p-layer, and that of the first n-layer, respectively, while a film thickness of the second i-layer is larger than that of the second p-layer, and that of the second n-layer, respectively;
a second insulating film provided between the first p-layer and the first i-layer;
a third insulating film provided between the first i-layer and the first n-layer;
a fourth insulating film provided between the second p-layer and the second i-layer; and
a fifth insulating film provided between the second i-layer and the second n-layer.

2. The solar cell according to claim 1, wherein the p-layer different from the first p-layer is a third p-layer, the p-layer different from the second p-layer is a fourth p-layer, the n-layer different from the first n-layer is a third n-layer, and the n-layer different from the second n-layer is a fourth n-layer, the first insulating film being provided between the third p-layer and the fourth p-layer as well as between the third n-layer and the fourth n-layer.

3. The solar cell according to claim 1, wherein the p-layer different from the first p-layer is a p-layer identical to the p-layer different from the second p-layer while the n-layer different from the first n-layer is a n-layer identical to the n-layer different from the second n-layer.

4. The solar cell according to claim 1, wherein the first through-electrode differs in Fermi level from the second through-electrode.

5. The solar cell according to claim 1, wherein the first p-layer differs in bandgap from the second p-layer, the first i-layer differs in bandgap from the second i-layer, and the first n-layer differs in bandgap from the second n-layer.

6. (canceled)

7. The solar cell according to claim 1, further comprising:
a first conductive film provided between the first insulating film and the second p-layer,
wherein the first conductive film is lower in absorptivity against light at a wavelength, absorbed by the second p-layer, the second i-layer, and the second n-layer, respectively, than the second p-layer, the second i-layer, and the second n-layer, respectively.

8. The solar cell according to claim 1, further comprising:
a solar cell connected to the first through-electrode or the second through-electrode,
wherein the solar cell includes a single pn junction or a single p-i-n junction.

9. A solar cell comprising:
a first p-layer;
a first n-layer;
a first i-layer provided between the first p-layer and the first n-layer;
a second p-layer;
a second n-layer;
a second i-layer provided between the second p-layer and second n-layer;
a first insulating film provided between the first p-layer and the second n-layer;
a first through-electrode penetrating through the first p-layer, the first n-layer, the first i-layer, the second p-layer, the second n-layer, the second i-layer, and the insulating film; and
a second through-electrode penetrating through the first p-layer, the first n-layer, the first i-layer, the second p-layer, the second n-layer, the second i-layer, and the insulating film, the second through-electrode differing in Fermi level from the first through-electrode,
wherein a film thickness of the first i-layer is larger than that of the first p-layer, and that of the first n-layer, respectively, while a film thickness of the second i-layer is larger than that of the second p-layer, and that of the second n-layer, respectively.

10. The solar cell according to claim 9, wherein the first through-electrode is connected to the first p-layer via a third p-layer to be connected to the second p-layer via a fourth p-layer, the second through-electrode is connected to the first n-layer via a third n-layer to be connected to the second n-layer via a fourth n-layer, and the first insulating film is provided between the third p-layer and the fourth p-layer as well as between the third n-layer and the fourth n-layer.

11. The solar cell according to claim 9, wherein the first through-electrode is connected to the first p-layer as well as the second p-layer via a third p-layer, and the second through-electrode is connected to the first n-layer as well as the second n-layer via a third n-layer.

12. The solar cell according to claim 9, wherein the first p-layer differs in bandgap from the second p-layer, the first i-layer differs in bandgap from the second i-layer, and the first n-layer differs in bandgap from the second n-layer.

13. The solar cell according to claim 9, further comprising:
a second insulating film provided between the first p-layer and the first i-layer;
a third insulating film provided between the first i-layer and the first n-layer;
a fourth insulating film provided between the second p-layer and the second i-layer; and
a fifth insulating film provided between the second i-layer and the second n-layer.

14. The solar cell according to claim 9, further comprising: a first conductive film provided between the first insulating film and the second p-layer,
wherein the first conductive film is lower in absorptivity against light at a wavelength, absorbed by the second p-layer, the second i-layer, and the second n-layer, respectively, than the second p-layer, the second i-layer, and the second n-layer, respectively.

15. The solar cell according to claim 9, further comprising:
a solar cell connected to the first through-electrode or the second through-electrode,
wherein the solar cell includes a single pn junction or a single p-i-n junction.
